(19) United States
(12) Patent Application Publication
(10) Pub. No.: US 2006/0156540 A1
(43) Pub. Date: Jul. 20, 2006

(54) Method for aligning a component on a printed circuit board

(75) Inventors: Daniel Cromwell, Penryn, CA (US); Alicia Castro, Isabela, PR (US); Xiang Dai, Roseville, CA (US); Joseph White, Windsor, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, L.P., Houston, TX (US)

(21) Appl. No.: 11/039,484

(22) Filed: Jan. 18, 2005

(51) Int. Cl. H05K 9/00; B23P 19/00; H05K 3/30

(52) U.S. Cl. 29/739; 174/377; 174/260; 29/759; 29/834; 29/832

(57) ABSTRACT

A fixture can be placed onto a printed circuit board in an aligned position and a component can be guided into the fixture and onto the printed circuit board. The fixture coarsely aligns the component with the printed circuit board.

### BACKGROUND OF THE INVENTION

During assembly of an electronic assembly, alignment of some parts can be difficult. For example, component placement onto a socket on a printed circuit board may result in a high failure rate and damage or destruction of expensive electronic components. Attachment structures of components may be fragile so that lateral relative movement of structures may cause breakage.

Likelihood of damage or destruction increases for components with a large pin count and tight pitch that impose challenging requirements for socket-to-board and integrated circuit-to-socket x-y alignment tolerances.

For manual assembly, results including yield, manufacturing costs, throughput, and the like may be highly dependent on operator training and experience. Assembly results in manual, automatic, and mixed manufacturing lines may be further influenced by alignment tolerances, handling precision, and the like.

In a specific example, a Land Grid Array (LGA) socket attachment design uses two alignment balls attached on integrated circuit (IC) pads through a typical Ball Grid Array (BGA) ball attachment process and a frameless LGA socket to meet tolerance specifications. The alignment ball and frameless socket approach may cause a challenging assembly problem, relatively poor socket handling compared to that for a framed socket and heavy dependence on operator skill in manually aligning an integrated circuit to the socket.

### SUMMARY

In accordance with an embodiment of a method for assembling an electronic circuit, a fixture can be placed onto a printed circuit board in an aligned position and a component can be guided into the fixture and onto the printed circuit board. The fixture coarsely aligns the component with the printed circuit board.

### BRIEF DESCRIPTION OF THE DRAWINGS

Embodiments of the invention relating to both structure and method of operation, may best be understood by referring to the following description and accompanying drawings whereby:

FIGS. 1A to 1E illustrate a sequence of perspective pictorial diagrams in an embodiment of a method for assembling an electronic circuit;

FIGS. 2A through 2E depict a sequence of two dimensional top pictorial views in an embodiment of another method for assembling an electronic circuit; and

FIGS. 3A and 3B respectively show a perspective pictorial view and an exploded pictorial view of a circuit assembly 300 that is constructed using a fixture.

### DETAILED DESCRIPTION

Mechanical fixtures and frames can be designed and used to improve the assembly process and/or integrated circuit component attachment to a board using a socket, thereby improving turn-on yield. The illustrative fixtures and frames can be used in an associated assembly process in a manufacturing environment to improve assembly personnel productivity, assembly throughput, and assembly defect rate. In various applications, the illustrative fixture and frame structures can be used in completely manual, completely automated, and partial manual and automated assembly processes.

In some embodiments, an illustrative socket fixture a socket fixture assists and improves coarse alignment for socket-to-board placement. In some embodiments, an illustrative integrated circuit, such as an Application Specific Integrated Circuit (ASIC), assists and improves coarse alignment for integrated circuit to socket placement. Socket fixtures and integrated circuit fixtures can be used in combination in an assembly process, or either type of fixture may be used alone in an assembly process.

By enabling and facilitating coarse alignment and/or supplying guides for socket-to-board and component-to-socket placements, lateral movement is reduced during socket and integrated circuit placement, guarding against socket frailty. Dependence on manual alignments by operators is reduced, thereby reducing process and result variations. Accordingly, significant improvements are attained in assembly personnel's expertise, assembly throughput, and reducing assembly defect rate and damage to components. Other improvements include better manufacturability and assistance in operator comfort, reducing eye-strain and the like.

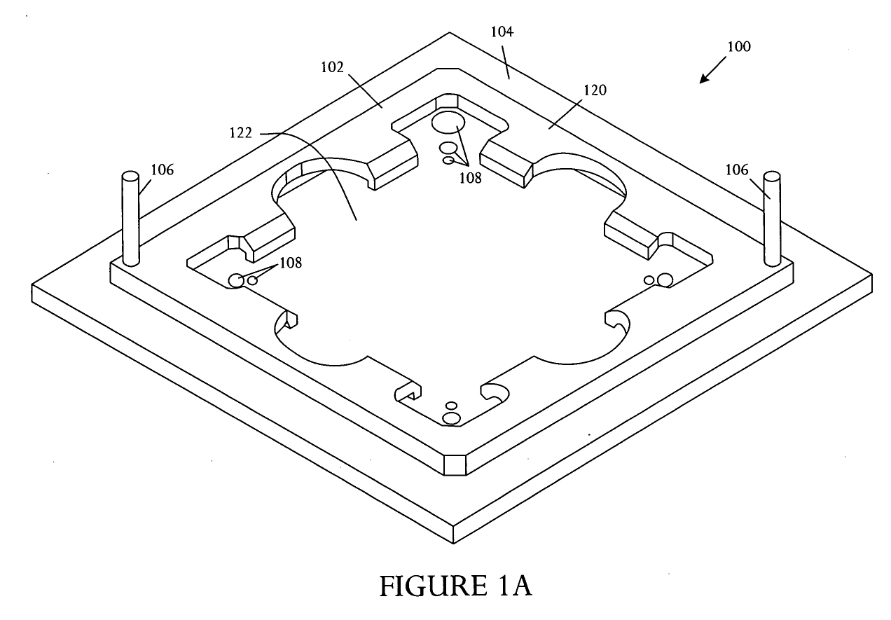

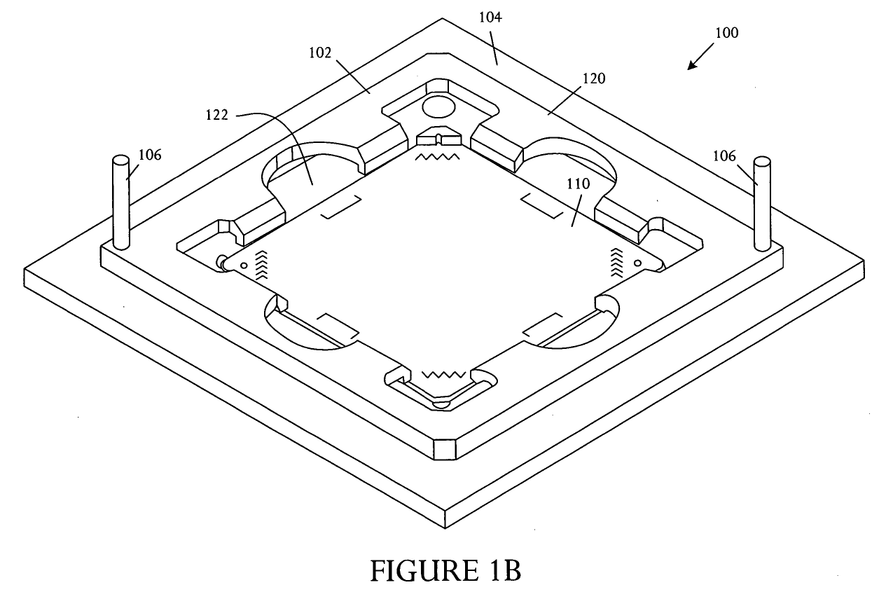

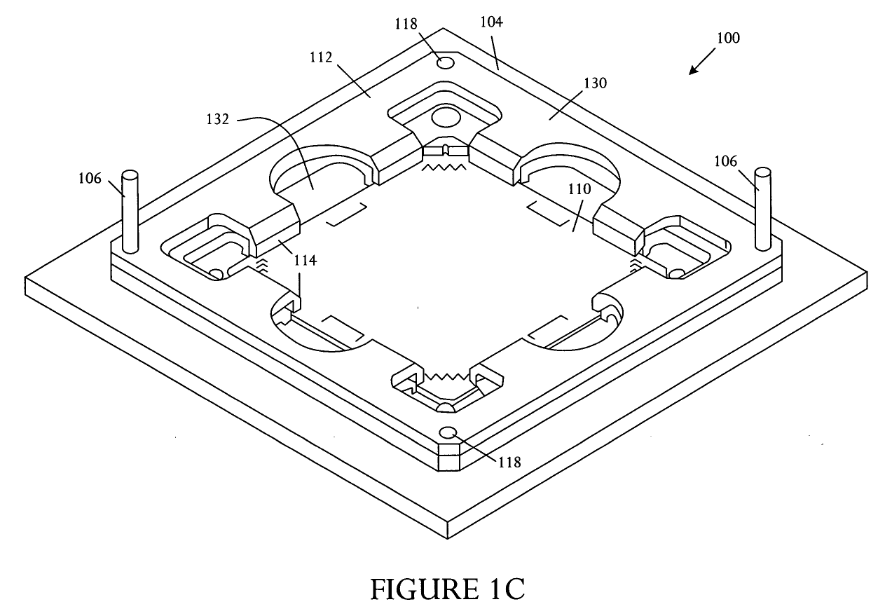

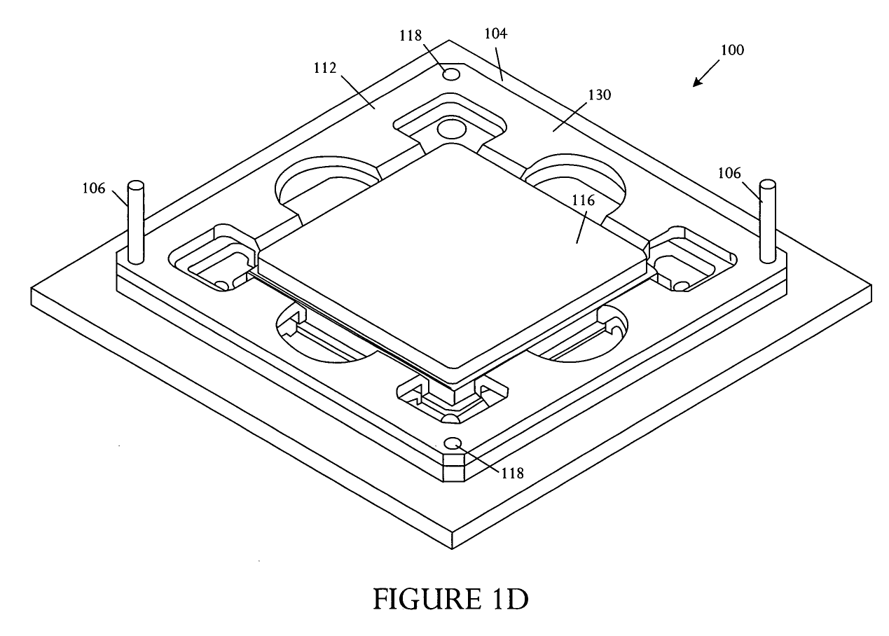

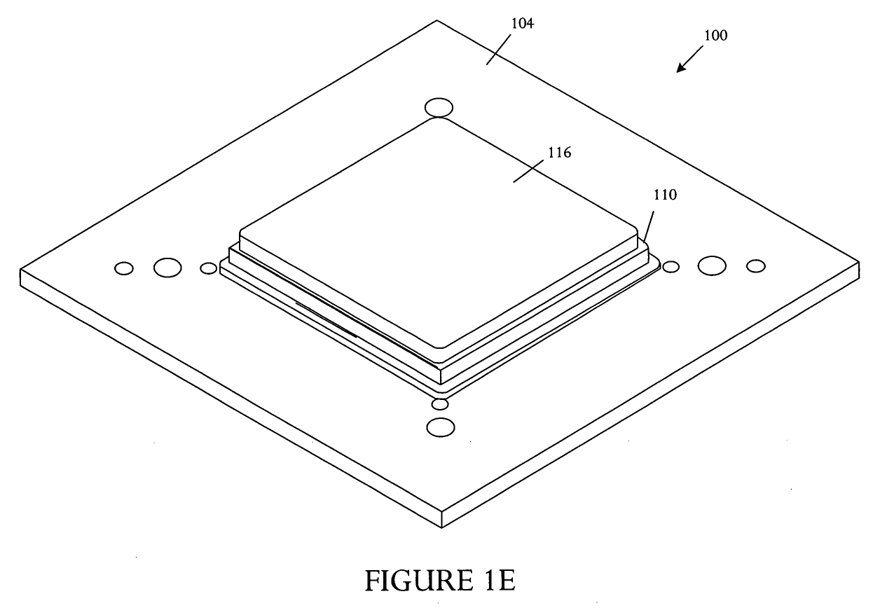

Referring to FIGS. 1A to 1E, a sequence of perspective pictorial diagrams illustrates an embodiment of a method for assembling an electronic circuit 100 using stacking frames. As shown in FIG. 1A, the method includes the action of placing a fixture 102 onto a printed circuit board 104 in an aligned position. The fixture 102 and printed circuit board 104 have alignment features, for example pins or balls and holes, that hold the fixture 102 in the aligned position with respect to the printed circuit board 104.

As shown in FIG. 1B, the method further includes the action of guiding a component 110 into the fixture 102 and onto the printed circuit board 104. The fixture 102 coarsely aligns the component 110 with the printed circuit board 104. The fixture 102 can be configured to prevent the component 110 from being placed in an incorrect orientation. For example, the component 110 can have a keyed corner with a corresponding feature in the fixture 102 to prevent mis-orientation. In the wrong orientation, the component will not seat but instead rocks or oscillates. Other examples of alignment structures include sized holes, pins, or balls, and placement of the structures to prevent insertion of the structures incorrectly. The structures are configured to attain proper insertion of devices.

In FIGS. 1A and 1B, the fixture is a socket fixture 102 that is placed onto the printed circuit board 104 in the aligned position. In the illustrative embodiment, the socket fixture 102 can be placed onto the appropriate site on the printed circuit board 104 in either of two orientations, in accordance with alignment features in the fixture 102 and board 104, for example aligning pins or balls in the fixture 102 with holes in the board 104. The component is a socket 110 that is placed into the socket fixture 102 and onto the printed circuit board 104. The socket fixture 102 coarsely aligns the socket 110 to printed circuit board placement.

The socket fixture 102 is placed, taking consideration of guide pins, balls, or rods to position the socket 110. The socket 110 is dropped in the socket fixture 102 which assures the socket 110 is placed in proper location, assists alignment of the socket 110 and protects the fragile contacts on the socket 110. The coarse alignment prevents sliding on the printed circuit board 104 to reduce lateral motion, rotation, or wipe on the board that can cause electrical connections to be damaged.

In the illustrative embodiment, the socket 110 is a socket that uses alignment ball receptors for alignment. The method facilitates component alignment, particular in conditions that component and printed circuit board alignment tolerances are defined by large pin count and tight pitch.

FIGS. 1A and 1B also show the socket fixture 102 with one or more handling rods 106 including a handling feature, for example a rod extending opposite the printed circuit board 104, and an alignment feature, for example a pin that is not shown and extends toward the printed circuit board 104. The pin engages with a printed circuit board alignment feature such as holes in the board.

In some embodiments, the handling rod alignment feature partially engages with the printed circuit board alignment feature during placement of the socket fixture 102 onto the printed circuit board 104 in the aligned position.

Referring to FIG. 1C, the method further comprises the action of placing an integrated circuit fixture 112 onto the printed circuit board 104 in the aligned position overlying the socket 110. The integrated circuit fixture 112 has securing features, for example tabs 114, which can be used to capture and secure the socket 110 onto the printed circuit board 104. The socket 110 may have one or more relatively large pins with crush ribs that only partially enter an opposing alignment hole in the printed circuit board 104. A subsequent pressing action seats the pin into the hole. The securing features hold the socket 110 so that the socket 110 is maintained in the correct position unable to move during ASIC 116 placement.

The integrated circuit fixture 112 is placed over the socket fixture 102 with holes 118 in the integrated circuit fixture 112 sliding over the handling rods 106 to ensure alignment. The integrated circuit fixture 112 can be pressed onto the printed circuit board 104 to fully engage and seat the socket 110 onto the printed circuit board 104.

In the illustrative embodiment, the integrated circuit fixture 112 can be positioned over the socket fixture 102 in any of four orientations, positions at which the corners of the fixtures 112 and 102 are aligned.

Referring to FIG. 1D, the method further comprises the action of guiding an integrated circuit 116 into the integrated circuit fixture 112 and onto the socket 110 on the printed circuit board 104. The integrated circuit fixture 112 coarsely aligns the integrated circuit 116 to socket placement. In some implementations, the integrated circuit feature 112 and integrated circuit 116 have matching chamfered corners, enforcing appropriate orientation of the integrated circuit 116 in the socket 110. The integrated circuit 116 is placed onto the socket 110 allowing the integrated circuit fixture 112 to guide placement. As long as the integrated circuit 116 does not rock on alignment balls and the chamfered corners of the integrated circuit 116 and socket 110 match, the integrated circuit 116 is both oriented and aligned.

The integrated circuit fixture 112 is placed over the socket fixture 102 with apertures in the integrated circuit fixture 112 engaged onto the handling rods 106. The integrated circuit fixture has one or more securing features 114 that secure the socket 110 in position on the printed circuit board 104.

The method further can comprise the action of lifting and removing the socket fixture 102 and the integrated circuit fixture 112 from the printed circuit board 104 by raising the handling rods 106 from the printed circuit board 104, leaving the socket 110, the integrated circuit 116, and the printed circuit board 104 as shown in FIG. 1E. In the depicted configuration, the fixtures are removed by lifting straight up on the handling rods and alignment pins 106.

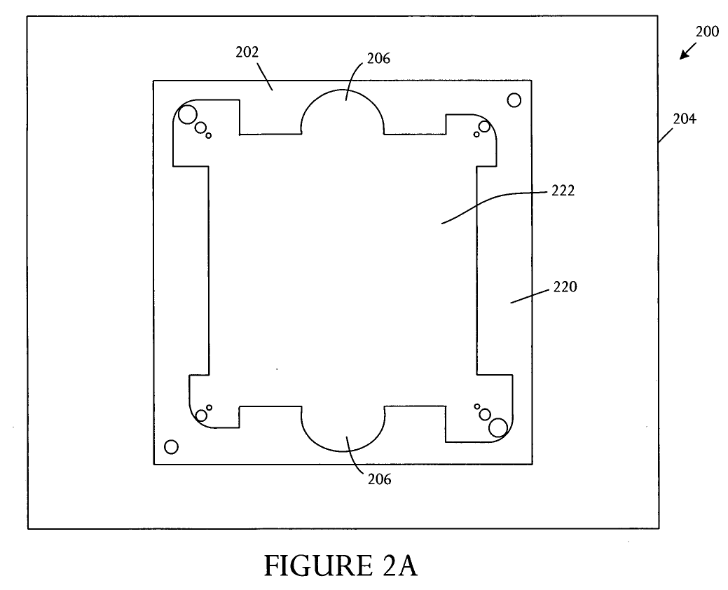

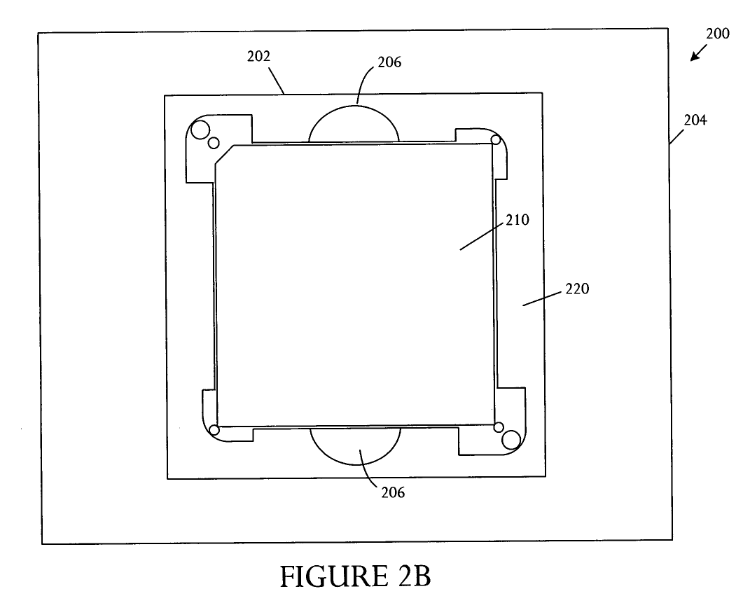

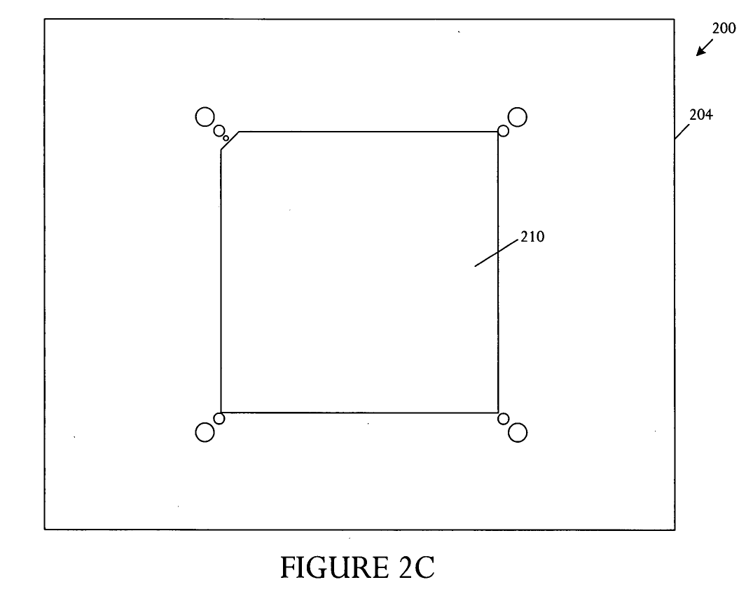

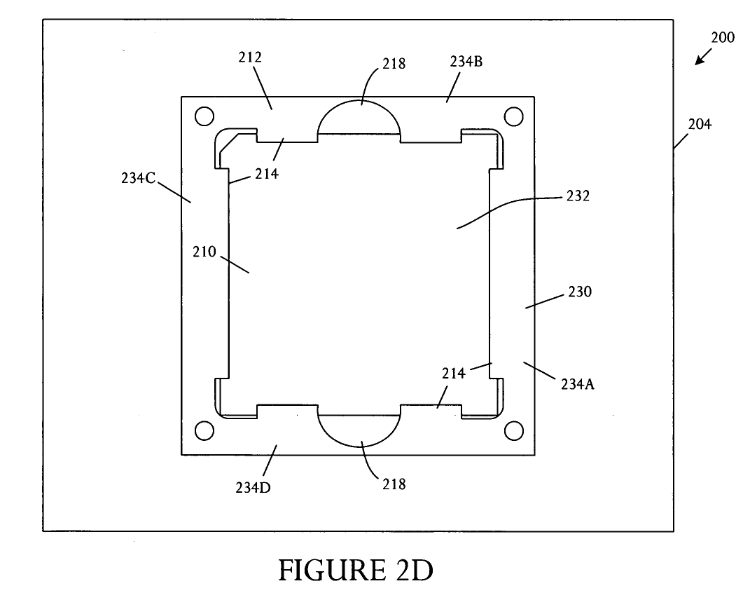

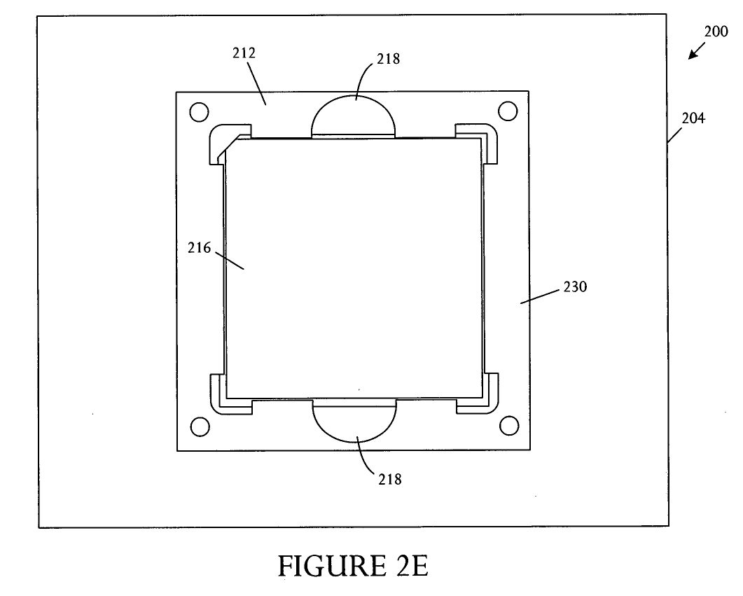

Referring to FIGS. 2A through 2E, a sequence of two dimensional top pictorial views depicts an embodiment of another method for assembling an electronic circuit 200. In a particular embodiment, a mechanical fixture and Electromagnetic Interference (EMI) containment frame can be implemented to improve the assembly process for an integrated circuit component to attach to a board via a Land Grid Array (LGA) socket. The socket fixture facilitates coarse alignment of a socket and can be removed immediately after socket placement. The EMI containment frame assists coarse alignment for the integrated circuit component to socket placement and also contains EMI during operation so that the EMI containment frame may be left attached after assembly is complete. In other embodiments, such as the embodiment shown in FIGS. 1A to 1E, both socket and integrated frames may be removed following assembly.

In FIG. 2A, the method includes the action of placing a socket fixture 202 onto a printed circuit board 204 in an aligned position. Again, the socket fixture 202 and printed circuit board 204 have alignment features holding the socket fixture 202 in the aligned position. In FIG. 2B the method includes the action of guiding a socket 210 into the socket fixture 202 and onto the printed circuit board 204 with the socket fixture 202 coarsely aligning the socket 210 with the printed circuit board 204.

Again, the socket 210 is a socket, for example either a frameless or framed socket, that uses alignment ball receptors for integrated circuit (ASIC) alignment, for example in conditions that socket, integrated circuit, and printed circuit board alignment tolerances are defined by large pin count and tight pitch.

FIGS. 2A and 2B also show the socket fixture 202 with one or more socket placement features 206, for example cut-outs, apertures, or finger cut-outs, and has alignment features, such as pins or balls that are not shown and extend toward the printed circuit board 204. The pins engage with printed circuit board alignment features such as holes in the board.

Referring to FIG. 2C, the socket fixture 202 is removed from the printed circuit board 204, leaving the socket 210 in place on the printed circuit board 204.

Referring to FIG. 2D, an Electromagnetic Interference (EMI) containment fixture 212 is placed onto the printed circuit board 204 in the aligned position overlying the socket 210. The EMI containment fixture 212 has securing features, for example tabs 214, that secure the socket 210 onto the printed circuit board 204. The EMI containment fixture 212 also includes handling features 218 to assist in handling and insertion of the integrated circuit 216.

In FIG. 2E, an integrated circuit 216 is guided into the EMI containment fixture 212 and onto the socket 210 on the printed circuit board 204. The EMI containment fixture 212 coarsely aligns and, together with the socket chamfer, orients the integrated circuit 216 to socket placement.

In various method embodiments that use multiple alignment fixtures or frames, the different frames can be aligned with the same holes on the printed circuit board, or different holes.

FIGS. 1A, 1C, 2A, and 2D depict examples of various fixtures 102, 112, 202, 212, for example capital tooling fixtures or an assembly tools set, that facilitate assembly in an electronic circuit. The various fixtures 102, 112, 202, 212 each comprise a frame assembly 120, 130, 220, 230 that fits around a perimeter of a component 110, 116, 210, 216 and has an interior aperture 122, 132, 222, 232. The fixtures 102, 112, 202, 212 further include alignment features on a base surface of the frame assembly 120, 130, 220, 230 that engage with alignment features on a printed circuit board 104, 204. The alignment features on the frame assemblies and the printed circuit boards can take various forms such as pins, ridges, beams, and the like that engage with holes, slots, depressions, and the like. The fixture 102, 112, 202, 212 coarsely aligns the component 110, 116, 210, 216 with the printed circuit board 104, 204.

The fixtures 102, 112, 202, 212 can be constructed from any suitable material, typically metals or plastics although other materials may be possible, based on the particular functionality desired.

In the illustrative embodiments, the component 110, 116, 210, 216 and the printed circuit board 104, 204 have alignment tolerances defined by large pin count and tight pitch, conditions for which the various fixtures 102, 112, 202, 212 are highly useful to eliminate or avoid damage resulting from component handling.

FIGS. 1A and 2A show examples of socket fixtures 102, 202 including a socket frame assembly 120, 220 that fits around a perimeter of a socket 110, 210 and coarsely aligns the socket 110, 210 to printed circuit board placement. The depicted sockets 110, 210 may be frameless sockets and can be aligned using appropriate structures.

FIGS. 1C and 2D illustrate examples of integrated circuit fixtures 112, 212 comprising an integrated circuit frame assembly 130, 230 that fits around a perimeter of an integrated circuit 116, 216 and coarsely aligns the integrated circuit 116, 216 to socket placement. The integrated circuit fixtures 112, 212 further comprise securing features such as tabs 114, 214 that secure a socket 110, 210 onto the printed circuit board 104, 204.

The embodiment shown in FIG. 2D includes an Electromagnetic Interference (EMI) containment fixture 212 comprising an electrically-conductive frame 230 with multiple members 234A, B, C, and D configured to fit around a perimeter of an integrated circuit 216 and tabs 214 for securing a socket 210 to the printed circuit board 204. Accordingly, the EMI containment frame 230 coarsely aligns the integrated circuit 216 to socket placement while holding the socket 210 in place on the printed circuit board 204 beneath the integrated circuit 216.

In FIGS. 1A to 1E, the depicted embodiment has a socket fixture 102 that includes one or more handling rods 106 including a handling feature, for example the rod extending away from the printed circuit board 104, and an alignment feature that engages with a printed circuit board alignment feature.

The integrated circuit fixture 112 shown in FIGS. 1C and 1D further comprises an integrated circuit frame assembly 130 that fits around the integrated circuit perimeter and is configured to overlie the socket fixture 102. In the example, the integrated circuit frame assembly 130 coarsely aligns the integrated circuit 116 to socket placement and has one or more apertures 118 to engage the handling rods 106. Tabs 114 function as securing features coupled to the integrated circuit frame assembly 130 to secure the socket 110 in position on the printed circuit board 104.

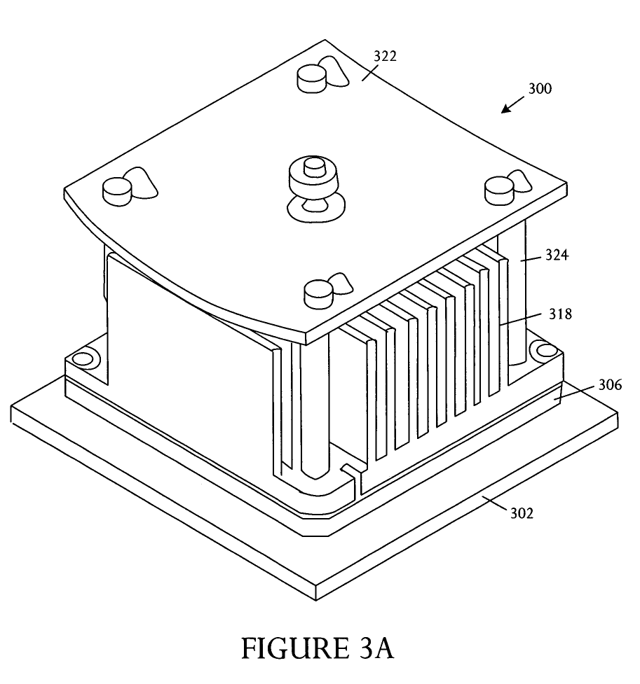

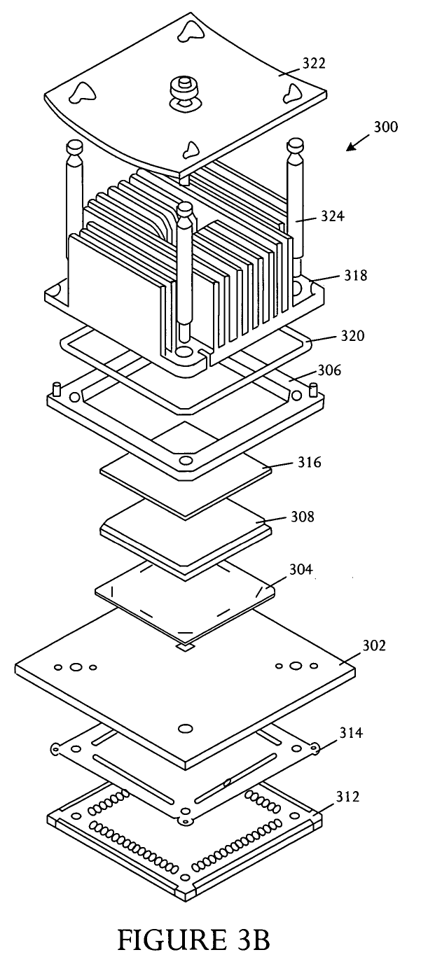

Referring to FIGS. 3A and 3B, a perspective pictorial view and an exploded pictorial view, respectively, of a circuit assembly 300 that is constructed using a fixture. The circuit assembly 300 comprises a printed circuit board 302, a frameless socket 304, an Electromagnetic Interference (EMI) containment fixture 306, and an integrated circuit 308. The frameless socket 304 is coupled to the printed circuit board 302 and can be coarsely aligned to printed circuit board placement using a socket fixture. The Electromagnetic Interference (EMI) containment fixture 306 is coupled to the printed circuit board 302, either directly or indirectly. The EMI containment fixture 306 further comprises securing features that secure the frameless socket 304 onto the printed circuit board 302. The integrated circuit 308 is coarsely aligned to frameless socket placement using the EMI containment fixture 306.

The exploded pictorial view shows the circuit assembly 300 configured in a plurality of structures stacked on a bolster plate assembly 312 on a base level with an insulator 314 inserted between the bolster plate assembly 312 and the printed circuit board 302. A Land Grid Array (LGA) frameless socket 304 is aligned and mounted on the printed circuit board 302. The integrated circuit 308, illustratively an Application Specific Integrated Circuit (ASIC), coarsely aligned with the LGA socket 304 through usage of the EMI containment fixture 306, is mounted to the LGA socket 304.

In some embodiments, the EMI containment fixture 306 can be fabricated from machined or molded metal, for example nickel-plated carbon steel. In other embodiments, EMI containment fixture 306 may be constructed from conductive materials other than metals, such as molded plastic with a conductive coating or molded with materials that result in conductive properties. In the folded structure, the EMI containment fixture 306 has multiple, for example four, connected members.

A thermal interface layer 316 inserted overlying the ASIC 308. The ASIC 308 and LGA socket 304 held interior to the EMI containment fixture or frame assembly 306. A heat sink 318 can be mounted overlying the ASIC 308 and the EMI containment fixture 306 with an EMI gasket 320 placed between the EMI containment fixture 306 and the heat sink 318. A load plate assembly 322 is connected overlying the heat sink 318 using load studs 324. The EMI gasket 320 can be attached to the EMI containment fixture members. An example of an EMI gasket is a clip-on gasket constructed from beryllium copper.

EMI containment is gained by grounding the entire electronic assembly 300 via ground traces formed on the printed circuit board 302. The EMI cage formed by the heat sink 318, EMI gasket 320, the EMI containment fixture 306, the printed circuit board 302, and bolster 312, is arranged to contain and form a shielding cage around the integrated circuit.

While the present disclosure describes various embodiments, these embodiments are to be understood as illustrative and do not limit the claim scope. Many variations, modifications, additions and improvements of the described embodiments are possible. For example, those having ordinary skill in the art will readily implement the steps necessary to provide the structures and methods disclosed herein, and will understand that the process parameters, materials, and dimensions are given by way of example only. The parameters, materials, and dimensions can be varied to achieve the desired structure as well as modifications, which are within the scope of the claims. For example, although particular types of components and circuit types are described, the illustrative structures and techniques may be used for any suitable components and circuit types. Furthermore, although the examples depict fixtures with particular relative sizes and shapes, the structures may be of any suitable type.

What is claimed is:

1. A method for assembling an electronic circuit comprising:
placing a fixture onto a printed circuit board in an aligned position; and
guiding a component into the fixture and onto the printed circuit board, the fixture coarsely aligning the component with the printed circuit board.

2. The method according to claim 1 wherein:
the fixture and printed circuit board have alignment features that hold the fixture in the aligned position with respect to the printed circuit board.

3. The method according to claim 1 further comprising:
placing a socket fixture onto the printed circuit board in the aligned position; and
guiding a socket into the socket fixture and onto the printed circuit board, the socket fixture coarsely aligning the socket to printed circuit board placement.

4. The method according to claim 3 further comprising:
removing the socket fixture from the printed circuit board, leaving the socket in place on the printed circuit board.

5. The method according to claim 4 further comprising:
placing an integrated circuit fixture onto the printed circuit board in the aligned position overlying the socket, the integrated circuit fixture having securing features that secure the socket onto the printed circuit board; and
guiding an integrated circuit into the integrated circuit fixture and onto the socket on the printed circuit board, the integrated circuit fixture coarsely aligning the integrated circuit to socket placement.

6. The method according to claim 5 wherein:
the socket is includes at least one alignment ball receptor.

7. The method according to claim 4 further comprising:
placing an Electromagnetic Interference (EMI) containment fixture onto the printed circuit board in the aligned position overlying the socket, the EMI containment fixture having securing features that secure the socket onto the printed circuit board; and
guiding an integrated circuit into the EMI containment fixture and onto the socket on the printed circuit board, the EMI containment fixture coarsely aligning the integrated circuit to socket placement.

8. The method according to claim 1 wherein:
the component and the printed circuit board have alignment tolerances defined by large pin count and tight pitch.

9. The method according to claim 1 further comprising:
placing a socket fixture onto a printed circuit board in an aligned position, the socket fixture having at least one handling rod including a handling feature and an alignment feature that engages with a printed circuit board alignment feature; and
guiding a socket into the socket fixture and onto the printed circuit board, the socket fixture coarsely aligning the socket with the printed circuit board.

10. The method according to claim 9 further comprising:
placing an integrated circuit fixture over the socket fixture with at least one aperture in the integrated circuit fixture being engaged onto the at least one handling rod, the integrated circuit fixture having at least one securing feature that secures the socket in position on the printed circuit board.

11. The method according to claim 10 further comprising:
partially engaging the handling rod alignment feature with the printed circuit board alignment feature during placement of the socket fixture onto the printed circuit board in the aligned position; and
pressing the integrated circuit fixture onto the printed circuit board to fully engage and seat the handling rod alignment feature with the printed circuit board alignment feature.

12. The method according to claim 10 further comprising:
guiding an integrated circuit into the integrated circuit fixture and onto the socket on the printed circuit board, the integrated circuit fixture coarsely aligning the integrated circuit to socket placement; and
lifting and removing the socket fixture and the integrated circuit fixture from the printed circuit board by raising the at least one handling rod from the printed circuit board.

13. A fixture apparatus that facilitates assembly in an electronic circuit comprising:
a frame assembly that fits around a perimeter of a component and has an interior aperture; and
alignment features on a base surface of the frame assembly that engage with alignment features on a printed circuit board, the fixture apparatus coarsely aligning the component with the printed circuit board.

14. The apparatus according to claim 13 further comprising:
a socket fixture including a socket frame assembly that fits around a perimeter of a socket and coarsely aligns the socket to printed circuit board placement.

15. The apparatus according to claim 13 further comprising:
a socket fixture including a socket frame assembly that fits around a perimeter of a socket and coarsely aligns the socket to printed circuit board placement, the socket having at least one alignment ball receptor.

16. The apparatus according to claim 13 further comprising:
an integrated circuit fixture comprising:
an integrated circuit frame assembly that fits around a perimeter of an integrated circuit and coarsely aligns the integrated circuit to socket placement; and
securing features that secure a socket onto the printed circuit board.

17. The apparatus according to claim 13 further comprising:
an Electromagnetic Interference (EMI) containment fixture comprising:
an electrically-conductive frame having a plurality of members configured to fit around a perimeter of an integrated circuit and coarsely aligns the integrated circuit to socket placement; and
securing features that secure a socket onto the printed circuit board.

18. The apparatus according to claim 13 further comprising:
a socket fixture further comprising:
a socket frame assembly that fits around a perimeter of a socket and coarsely aligns the socket to printed circuit board placement; and
at least one handling rod including a handling feature and an alignment feature that engages with a printed circuit board alignment feature.

19. The apparatus according to claim 18 further comprising:
an integrated circuit fixture further comprising:
an integrated circuit frame assembly that fits around a perimeter of an integrated circuit and is configured to overlie the socket fixture, the integrated circuit frame assembly coarsely aligning the integrated circuit to socket placement, the integrated circuit frame assembly having at least one aperture that engages onto the at least one handling rod; and
at least one securing feature coupled to the integrated circuit frame assembly that secures the socket in position on the printed circuit board.

20. The apparatus according to claim 13 wherein:
the component and the printed circuit board have alignment tolerances defined by large pin count and tight pitch.

21. A circuit assembly comprising:
a printed circuit board;
a socket coupled to the printed circuit board and coarsely aligned to printed circuit board placement using a socket fixture;
an Electromagnetic Interference (EMI) containment fixture coupled to the printed circuit board and to the socket, the EMI containment fixture further comprising securing features that secure the socket onto the printed circuit board; and
an integrated circuit that is coarsely aligned to socket placement using the EMI containment fixture.

22. The circuit assembly according to claim 21 wherein:
the integrated circuit, the socket, and the printed circuit board have alignment tolerances defined by large pin count and tight pitch.
